(19) United States
(12) Patent Application Publication
(10) Pub. No.: US 2013/0273717 A1
(43) Pub. Date: Oct. 17, 2013

(54) Apparatus and Method for the Singulation of a Semiconductor Wafer

(71) Applicants: Chien Ling Hwang, Hsinchu City (TW); Yi-Li Hsiao, Hsinchu City (TW); Bor-Ping Jang, Chu-Bei (TW); Hsin-Hung Liao, Hsinchu (TW); Lin-Wei Wang, Zhubei City (TW); Chung-Shi Liu, Hsinchu City (TW)

(72) Inventors: Chien Ling Hwang, Hsinchu City (TW); Yi-Li Hsiao, Hsinchu City (TW); Bor-Ping Jang, Chu-Bei (TW); Hsin-Hung Liao, Hsinchu (TW); Lin-Wei Wang, Zhubei City (TW); Chung-Shi Liu, Hsinchu City (TW)

(73) Assignee: Taiwan Semiconductor Manufacturing Co., Ltd., Hsin-Chu (TW)

(21) Appl. No.: 13/448,648

(22) Filed: Apr. 17, 2012

(51) Int. Cl. H01L 21/78; B24B 7/10; B23K 26/38; B26D 7/01

(52) U.S. Cl. 438/463; 438/460; 83/451; 451/259; 219/385; 451/548; 219/476; 257/E21.599

(57) ABSTRACT

The present disclosure is directed to an apparatus for the singulation of a semiconductor substrate or wafer. In some embodiments the singulation apparatus comprises a plurality of cutting devices. The cutting devices are configured to form multiple concurrent cutting lines in parallel on a surface of the semiconductor wafer. In some embodiments, the singulation apparatus comprises at least two dicing saws or laser modules. The disclosed singulation apparatus can dice the semiconductor wafer into individual chips by dicing in a direction across a complete circumferential edge of the wafer, thereby decreasing process time and increasing throughput.

### BACKGROUND

An individual integrated circuit or chip is generally formed from a larger structure known as a semiconductor wafer. Each semiconductor wafer has a plurality of integrated circuits arranged in rows and columns. Typically, the wafer is sawn or “diced” into rectangularly shaped discrete integrated circuits along two mutually perpendicular sets of parallel lines or “streets” lying between each of the rows and columns thereof.

### BRIEF DESCRIPTION OF THE DRAWINGS

FIG. 1 illustrates a perspective view of a dicing apparatus in accordance with an embodiment of the disclosure.

FIG. 2 illustrates a perpsective view of an embodiment of a dicing apparatus in accordance with an embodiment of the disclosure including a transmission mechanism having gears.

FIG. 3 illustrates a perspective view of an alternative embodiment of the dicing apparatus of FIG. 2 including a transmission mechanism having a pulley and belt.

FIG. 4 illustrates a perspective view of an embodiment of a dicing apparatus in accordance with the disclosure having opposable pairs of dicing blades.

FIG. 5 illustrates a perspective view of an embodiment of a dicing apparatus in accordance with the apparatus having dicing blades simultaneously operable in a first direction and in a second direction perpendicular thereto.

FIG. 6 illustrates a perspective view of a further embodiment of a dicing apparatus in accordance with the disclosure including cutting devices comprising laser modules.

FIG. 7 illustrates a perspective view of an embodiment of the dicing apparatus of FIG. 6 with the apparatus including laser modules having rotational mirrors.

FIG. 8 illustrates a perspective view of an embodiment of a dicing apparatus in accordance with the disclosure having laser modules arranged in a consecutive configuration.

FIG. 9 illustrates a flow diagram of some embodiments of a method for singulation of a semiconductor wafer.

### DETAILED DESCRIPTION

The description herein is made with reference to the drawings, wherein like reference numerals are generally utilized to refer to like elements throughout, and wherein the various structures are not necessarily drawn to scale. In the following description, for purposes of explanation, numerous specific details are set forth in order to facilitate understanding. It may be evident, however, to one of ordinary skill in the art, that one or more aspects described herein may be practiced with a lesser degree of these specific details. In other instances, known structures and devices are shown in block diagram form to facilitate understanding.

In the process of singulation or dicing of a semiconductor wafer, a number of rectangular regions are sectioned on the surface of a semiconductor wafer by streets that are arranged in a lattice form, and a semiconductor circuit is arranged in each of the rectangular regions. The semiconductor wafer is separated along the streets into individual rectangular regions to obtain semiconductor chips. A cutting machine used for separating the semiconductor wafer along the streets typically involves dicing with a rotating blade or a laser beam. Dicing saw blades can be in the form of an annular disc that is either clamped between the flanges of a hub or built on a hub that accurately positions the thin flexible saw blade which carries diamond particles as the abrasive material.

Although saw singulation works well, continuing advancements in the semiconductor industry have tested the limitations of saw singulation. One such advancement is the increase in wafer size. Singulation of a larger area utiziling current techniques involves the use of single or dual dicing blades or a single laser head, row by row, in sequence. A blade of a wafer saw or a laser beam is passed through the surface of the semiconductor wafer by moving either the blade or beam relative to the wafer or the table of the saw and the wafer relative to a stationary blade or beam, or a combination of both. The blade or beam cuts precisely along each street, returning back over the wafer while the wafer is laterally indexed to the next cutting location. Once all cuts associatd with mutually parallel streets having one orientation are complete, either the blade is rotated 90° relative to the wafer or the wafer is rotated 90°, and cuts are made through streets in a direction perpendicular to the initial direction of cut. This results in a time-consuming process.

In a conventional process, a singulation blade is generally operated at a rotational (spindle) speed of 20,000 rotations per minute (RPM), and a table speed of two inches per second (IPS). These speeds are typical of a conventional “Disco” type singulation machine. As is commonly understood in the art, the table speed measures the (linear) speed of the blade moving along a molded strip during singulation of the molded strip, whereas the spindle speed approximates the rotational speed of the blade (about its axis), as the blade cuts through the molded strip.

The relatively slow conventional speeds are used in the art to reduce blade overheating, to preserve blade life, and to reduce the number of defects in the singulated product. As mentioned above, speeding up the singulation process is beneficial to improve throughput and thereby reduce costs associated with semiconductor manufacturing.

Accordingly, the present disclosure is directed to an apparatus for the singulation of a semiconductor wafer. In some embodiments the disclosed apparatus comprises a plurality of cutting devices. The cutting devices may comprise at least two dicing blades or laser modules. The cutting devices are operable to dice a semiconductor wafer across an entire circumferential edge of the wafer, thereby eliminating the necessity for dicing single rows or streets in sequence, increasing throughput and decreasing processing time.

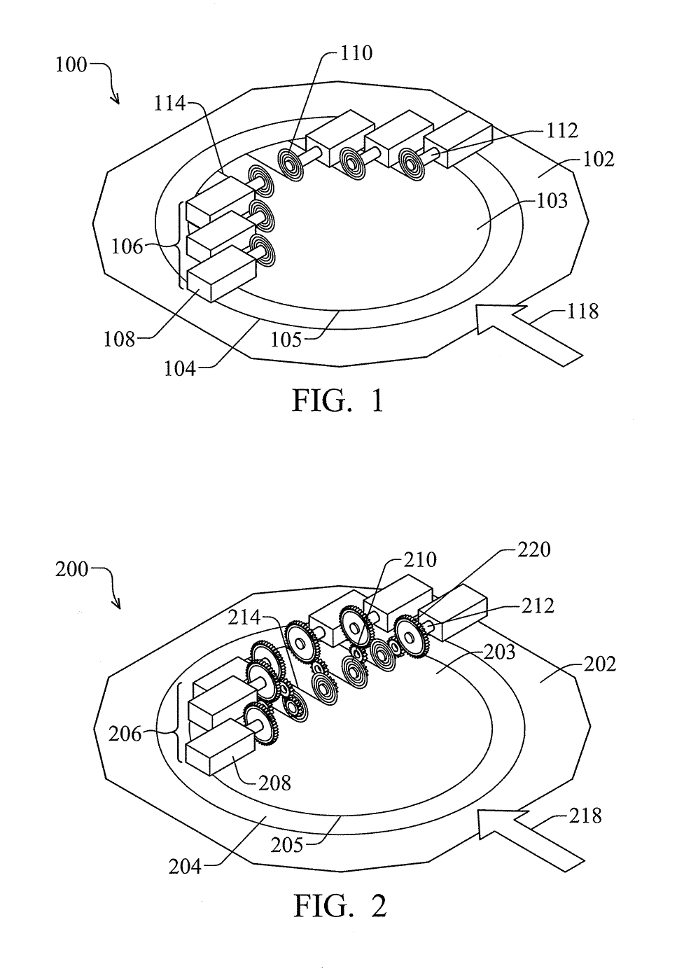

As shown in FIG. 1, there is illustrated a first embodiment of an apparatus 100 for singulation of a semiconductor. A semiconductor substrate support 102 is configured to support a wafer 103 or other semiconductor substrate to be diced. The wafer 103 is mounted to support 102 by mechanical, adhesive or vacuum means, as is known in the art, for example, with dicing tape 104. A plurality of cutting devices 106, illustrated as dicing saws, are arranged in a U-shape across a complete circumferential edge 105 of the wafer 103. It will be understood that while six (6) dicing saws 106 are illustrated in FIG. 1, there will typically be at least two dicing saws 106, with the maximum number of dicing saws 106 being limited only by the size of the wafer 103 to be diced. Dicing saws 106 include a motor 108. A dicing blade 110 is attached to a spindle 112 rotatably connected to the motor 108. Dicing saws 106 may be mounted to an arm suspended by a support (not shown) to hold dicing saws 106 from above.

During operation of the dicing saws 106, dicing blade 110 of the dicing saw 106 is passed through a surface of the semiconductor wafer 103 by movement of the wafer 103 in wafer feed direction 118, while dicing saws 106 remain in a static position. Dicing blades 110 will concurrently cut wafer 103 to produce multiple cutting lines 114 simultaneously in parallel across an entire circumferential edge 105 of wafer surface. In one embodiment, semiconductor wafer 103 can then be rotated 90° and cuts are made in a second direction perpendicular to the first direction of the cutting lines 114. In another embodiment, dicing saws 106 can be rotated 90° by movement arm suspended by support (not shown) holding dicing saws 106 from above.

Distance between cutting lines 114 may be adjusted to account for variable sizes of circuits arranged on the semiconductor wafer 103. Dicing saws 106 are moveable in an axial direction to adjust distance between cutting lines 114. In this manner, wafer 103 may be diced to provide circuits of all the same size, or various size circuits may be cut on the same wafer 103.

In FIG. 2 there is illustrated a further embodiment of the singulation apparatus disclosed herein. In this embodiment, apparatus 200 includes a support 202 on which a semiconductor wafer 203 can be mounted, such as by dicing tape 204. A plurality of dicing saws 206 are arranged across a complete circumferential edge 205 of the wafer 203. Dicing saws 206 comprise a motor 208 to which a dicing blade 210 is mounted by a spindle 212. Dicing saws 206 further include a transmission mechanism 220 , illustrated as a set of gears, affixed between motor 208 and dicing blade 210. Transmission mechanism 220 is employed such that dicing saws are stepped so as to prevent interference of dicing saws 206 as dicing of the semiconductor wafer 203 proceeds by movement of the wafer 203 in the direction of arrow 218 to provide concurrent cutting of wafer 203 along cutting lines 214.

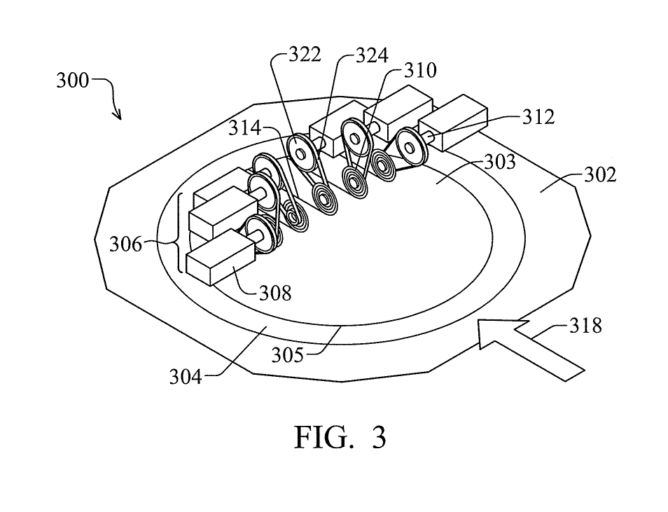

FIG. 3 illustrates an additional embodiment of the transmission mechanism of the dicing saw of FIG. 2. Apparatus 300 comprises a support 302 to which is mounted a semiconductor wafer 303, as by dicing tape 304. A plurality of dicing saws 306 are arranged along an entire circumferential edge 305 of the wafer 303. Dicing saws 306 include a transmission mechanism. In this embodiment, transmission mechanism comprises a pulley 322 and belt 324 design. Pulley 322 includes a grooved wheel attached to spindle 312 which is rotatably connected to motor 308. A belt 324 is threaded around grooved wheel of pulley 322 and around dicing blade 310. Transmission mechanism is stepped so as to prevent interference of dicing saws 306 as dicing of the semiconductor wafer 303 proceeds.

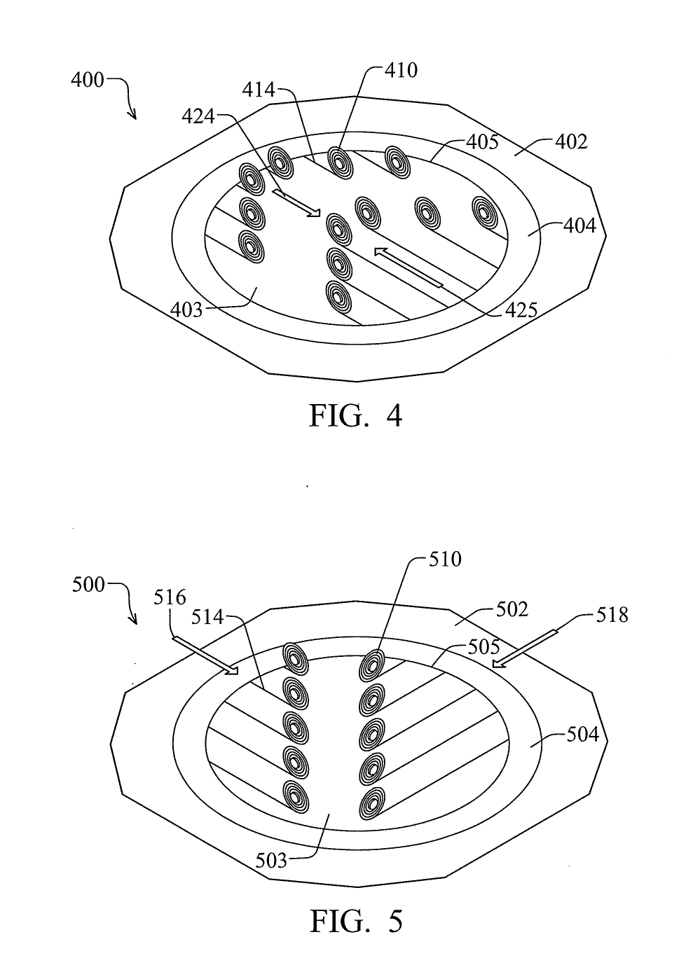

A further embodiment of the singulation apparatus disclosed herein is illustrated in FIG. 4. In FIG. 4, dicing blades 410 are arranged to form multiple opposable pairs of dicing blades 410 across a complete circumferential edge 405 of the semiconductor wafer 403. Each pair of dicing blades 410 operates to form a single cutting line 414. In operation, semiconductor wafer 403 remains in a static position and pairs of dicing blades 410 move in opposing directions as indicated by directional arrows 424, 425.

FIG. 5 illustrates a still further embodiment of the singulation apparatus disclosed herein. In the embodiment illustrated, a plurality of dicing blades 510 are configured across a complete circumferential edge 505 of semiconductor wafer 503 such that when dicing proceeds, the cutting devices 510 operate to form cutting lines 514 along respective perpendicular axes along the wafer 503 surface. Thus, dicing is performed simultaneously in a first direction 516 and in a second direction 518 perpendicular to the first direction 516.

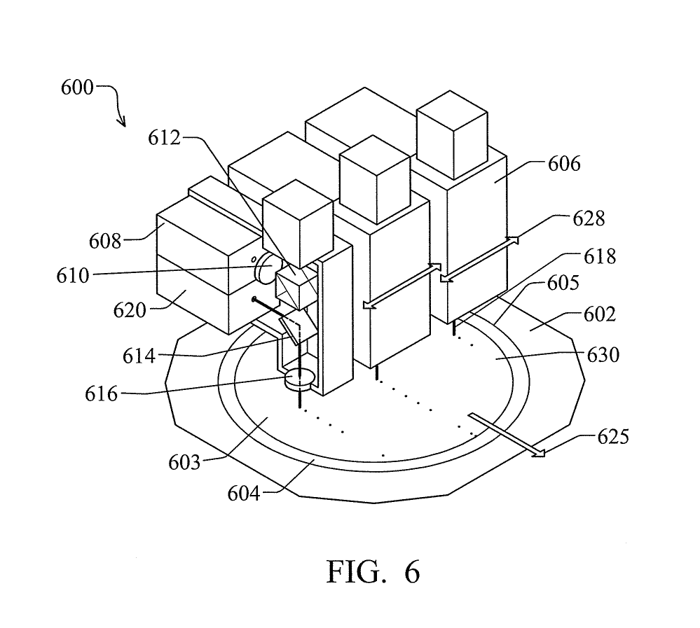

FIG. 6 illustrates a further embodiment of the singulation apparatus disclosed herein. Apparatus 600 includes a substrate support 602 on which a semiconductor wafer 603 is supported. The wafer 603 is releasably mounted to the support 602 with wafer dicing tape 604. A plurality cutting devices 606, illustrated as laser modules 606, are configured across a complete circumferential edge 605 of wafer 603. Laser modules 606 include optical devices, such as light source 608, collimater 610, beam splitter 612, mirror 614, and lens 616. Laser beam 618 is generated by laser source 620. Laser modules 606 are moveable in an axial direction 628 so as to adjust distance between cutting lines 630. In operation, wafer 603 is advanced in feed direction 625. Laser source 620 generates laser beam 618 to form cutting lines 630.

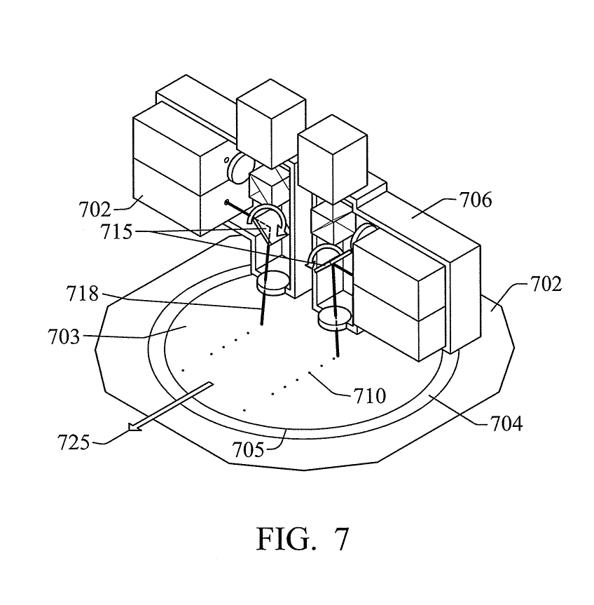

In FIG. 7 there is illustrated an additional embodiment of the singulation apparatus. Apparatus 700 comprises a support 702 to which is mounted a semiconductor wafer 702 as by dicing tape 704. A plurality of laser modules 706 are arranged along a complete circumferential edge 705 of the wafer 703. In this embodiment, laser modules 706 include rotational mirrors 715 which operate to adjust a reflection angle of the laser. In this manner, the distance between cutting lines 710 may be adjusted by rotation of the reflection angle of the laser, while the laser modules 706 remain in a static position. In operation, laser source 720 generates laser beam 718 to form cutting lines 710 as wafer 703 proceeds in wafer feed direction 725.

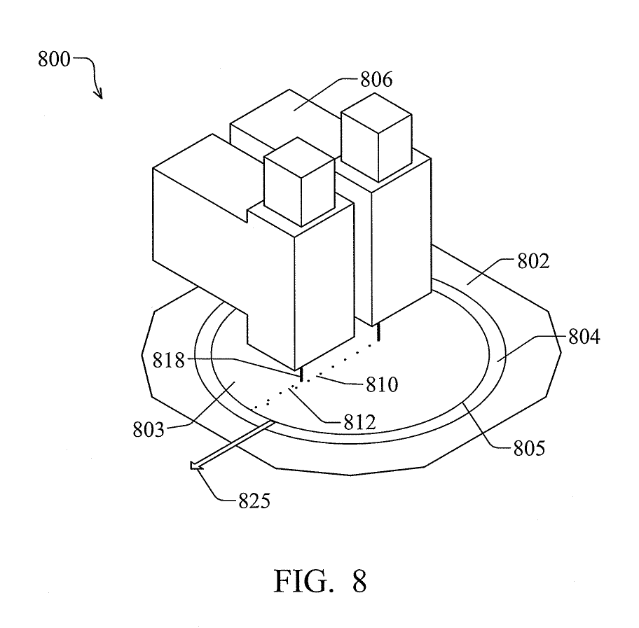

Referring to FIG. 8, another illustrated embodiment of the singulation apparatus is shown having laser modules 806 arranged consecutively along wafer feed direction 825. Semiconductor wafer 803 is mounted to substrate support 802 by dicing tape 804. As wafer 803 moves in feed direction 825, a first cutting line 810 is formed by laser beam 818 on wafer 803 surface. Consecutive laser modules 806 then form cutting lines 812 along cutting line 810 such that dicing may be processed in a single scan.

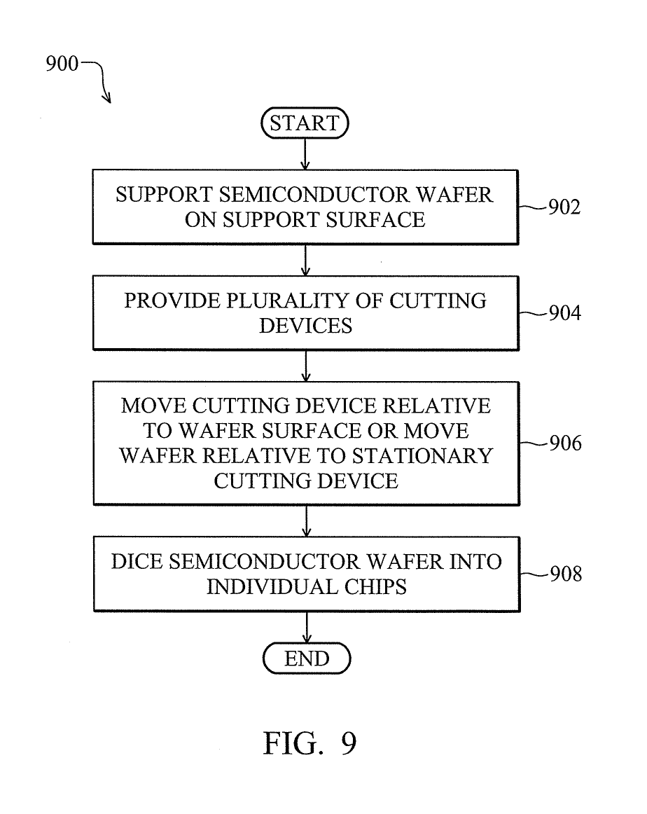

FIG. 9 illustrates a flow diagram of some embodiments of a method 900 for singulation of a semiconductor wafer with a plurality of conducting devices. While method 900 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At step 902 a semiconductor wafer is arranged on a support surface configured to hold wafer. Support surface may be moveable in order to move wafer during dicing process.

At step 904, a plurality of cutting devices is assembled to dice the semiconductor wafer. The cutting devices may comprise at least two dicing blades or laser modules. Cutting devices are moveable in an axial direction along the circumferential edge of the semiconductor wafer.

At 906, cutting devices are moved relative to the semiconductor wafer on the support surface relative to the support surface, or the support surface holding the wafer is moved while cutting devices remain stationary. Dicing of the semiconductor wafer into individual chips by formation of multiple concurrent cutting lines then proceeds at step 908.

It will be appreciated that equivalent alterations and/or modifications may occur to one of ordinary skill in the art based upon a reading and/or understanding of the specification and annexed drawings. The disclosure herein includes all such modifications and alterations and is generally not intended to be limited thereby. In addition, while a particular feature or aspect may have been disclosed with respect to only one of several implementations, such feature or aspect may be combined with one or more other features and/or aspects of other implementations as may be desired. Furthermore, to the extent that the terms “includes”, “having”, “has”, “with”, and/or variants thereof are used herein, such terms are intended to be inclusive in meaning—like “comprising.” Also, “exemplary” is merely meant to mean an example, rather than the best. It is also to be appreciated that features, layers and/or elements depicted herein are illustrated with particular dimensions and/or orientations relative to one another for purposes of simplicity and ease of understanding, and that the actual dimensions and/or orientations may differ substantially from that illustrated herein.

Therefore, the disclosure relates to An apparatus for the singulation of a semiconductor wafer including a semiconductor substrate support. A plurality of cutting devices are provided to concurrently cut a surface of the semiconductor wafer to form multiple cutting lines.

In another embodiment, the disclosure relates to a method for the singulation of a semiconductor wafer. The method comprises supporting a semiconductor wafer on a support surface. The method further comprises providing a plurality of cutting devices and cutting the semiconductor wafer with the plurality of cutting devices, the cutting devices operable to form multiple concurrent cutting lines on a surface of the semiconductor wafer.

In a still further embodiment, the disclosure relates to an apparatus for the singulation of a semiconductor wafer. The apparatus comprises at least two cutting devices, the cutting devices comprising dicing blades or laser modules and being operable to perform the concurrent dicing of the wafer in a direction across a complete circumferential edge of the wafer.

What is claimed is:

1. An apparatus for the singulation of a semiconductor wafer, comprising:
a semiconductor wafer support; and
a plurality of cutting devices, the cutting devices providing concurrent cutting of a surface of the semiconductor wafer to simultaneously form multiple cutting lines in parallel.

2. The apparatus of claim 1, wherein the cutting devices are moveable in an axial direction to adjust a distance between cutting lines.

3. The apparatus of claim 1, wherein the cutting devices comprise at least two dicing saws or laser modules.

4. The apparatus of claim 3, wherein the dicing saws comprise a dicing blade, each dicing blade including a transmission mechanism.

5. The apparatus of claim 4, the transmission mechanism comprising a gear or a pulley and belt.

6. The apparatus of claim 3, wherein the dicing saws comprise multiple opposable pairs of dicing blades, each pair operating to form a single cutting line.

7. The apparatus of claim 3, wherein the dicing saws operate to form cutting lines along respective perpendicular axes along the wafer surface.

8. The apparatus of claim 3, wherein the dicing saws are arranged to form a U-shaped configuration across a complete circumferential edge of the semiconductor wafer.

9. The apparatus of claim 3, the cutting devices comprising at least two laser modules.

10. The apparatus of claim 9, wherein each laser module further comprises a rotational mirror to adjust a reflection angle of the laser.

11. The apparatus of claim 9, wherein the laser modules are arranged consecutively along a wafer feed direction.

12. A method for the singulation of a semiconductor wafer comprising:
supporting a semiconductor wafer on a support surface;
providing a plurality of cutting devices; and
cutting the semiconductor wafer with the plurality of cutting devices, the cutting devices operable to form multiple concurrent cutting lines on a surface of the semiconductor wafer.

13. The method of claim 12, wherein, in the cutting step, the cutting devices comprise at least two dicing saws or laser modules.

14. The method of claim 12, wherein cutting of the semiconductor wafer occurs in a first direction across a complete circumferential edge of the wafer.

15. The method of claim 14, further comprising rotating by 90° the cutting devices relative to the semiconductor wafer or semiconductor wafer relative to the cutting devices.

16. The method of claim 15, further comprising cutting of the wafer in a second direction perpendicular to the first direction.

17. An apparatus for the singulation of a semiconductor wafer comprising at least two cutting devices, the cutting devices comprising dicing blades or laser modules and being operable to perform the concurrent dicing of the wafer in a direction across a complete circumferential edge of the wafer.

18. The apparatus of claim 17, the cutting devices being operable to perform simultaneous dicing in a first direction and in a second direction perpendicular thereto.

19. The apparatus of claim 17, wherein the cutting devices are moveable in an axial direction to adjust a distance between cutting lines.

20. The apparatus of claim 17, further comprising a semiconductor wafer support, the support comprising mechanical, vacuum or adhesive means to mount the semiconductor wafer to the support.
